(19) United States
(12) Patent Application Publication
(10) Pub. No.: US 2011/0235815 A1
(43) Pub. Date: Sep. 29, 2011

(54) METHOD AND ARRANGEMENT FOR AUDIO SIGNAL PROCESSING

(75) Inventor: Per HISELIUS, Lund (SE)

(73) Assignee: Sony Ericsson Mobile Communications AB, Lund (SE)

(21) Appl. No.: 12/762,429

(22) Filed: Apr. 19, 2010

Related U.S. Application Data
(60) Provisional application No. 61/317,811, filed on Mar. 26, 2010.

(51) Int. Cl. H03G 3/00

(52) U.S. Cl. 381/62

(57) ABSTRACT

A method of processing an audio signal with a content is disclosed. The method comprises determining, based on an analysis associated with a missing fundamental phenomenon, a frequency region suitable for adding one or more harmonic tones of a fundamental tone, determining one or more spectral properties of the content within the frequency region, and adjusting operation of a function for adding harmonic tones based on the spectral properties. Corresponding computer program product, audio signal processing arrangement and electronic device is also disclosed.

### TECHNICAL FIELD

The present invention relates generally to the field of processing of audio signals. More particularly, it relates to audio signal processing in the context of missing fundamental enhancement algorithms.

### BACKGROUND

Reproducing relatively low frequency portions of an audio signal (e.g. bass portions of an audio signal with musical content) generally requires either or both of a large loudspeaker area and maximum amplitude to be able to move the required amount of air (or other relevant medium) so that a pressure at the eardrum of a listener is sufficient. Consequently, these needs are less pronounced (but not irrelevant) for a loudspeaker that is designed to be worn in or in the vicinity of an ear (such as an earphone).

It is well known in the art of audio signal processing that the impression of bass in an audio signal may be enhanced by addition of harmonics of a bass fundamental tone to the audio signal without adding the fundamental tone itself. The harmonic tones suggest a fundamental tone even if the sound lacks a component at the fundamental frequency itself. The enhanced impression of bass is due to that the brain perceives the pitch of a tone not only by its fundamental frequency, but also via the higher harmonics. Thus, the brain of a listener assumes that the fundamental tone is there when the harmonic tones are registered, and therefore the listener may perceive the same pitch (perhaps with a different timbre) even if the fundamental frequency is missing from a tone. This phenomenon is commonly referred to as the missing fundamental phenomenon or psychoacoustic bass enhancement.

Such addition of harmonic tones is particularly applicable to audio signals associated with musical content. The enhancement process may be particularly useful when the audio content is to be reproduced by small loudspeakers as mentioned above.

It is a problem, however, with missing fundamental enhancement that the addition of harmonics is very well perceived when applied to some content (e.g. pop music) while it is perceived as distortion when applied to other content (e.g. piano music). Thus, a technical problem with the prior art is how to determine whether or not missing fundamental enhancement should be used.

Therefore, there is a need for improved methods and arrangements of audio signal processing in relation to missing fundamental enhancement.

### SUMMARY

It should be emphasized that the term “comprises/comprising” when used in this specification is taken to specify the presence of stated features, integers, steps, or components, but does not preclude the presence or addition of one or more other features, integers, steps, components, or groups thereof.

Embodiments of the invention obviate at least some of the above disadvantages and provide improved methods and arrangements of audio signal processing in relation to missing fundamental enhancement.

According to a first aspect of the invention this is achieved by a method of processing an audio signal with a content. The method comprises determining, based on an analysis associated with a missing fundamental phenomenon, a frequency region suitable for adding one or more harmonic tones of a fundamental tone, determining one or more spectral properties of the content within the frequency region, and adjusting operation of a function for adding harmonic tones based on the spectral properties.

The analysis may, for example, comprise a missing fundamental analysis. The frequency region may be a frequency interval, or it may be a frequency region with one or two open ends. The fundamental tone may be a missing fundamental tone. The fundamental tone may be a tone which was present in an original audio signal but which has been excluded by signal processing (e.g. filtered out) so that it is no longer present in the audio signal.

In some embodiments, the step of determining one or more spectral properties of the content within the frequency region may comprise determining, via spectrum analysis, a value indicating an extent to which energy or power of the content is concentrated around one or more particular frequencies within the frequency region.

In some embodiments, the step of determining one or more spectral properties of the content within the frequency region may comprise reading metadata associated with the content and comprising information relating to a value indicating an extent to which energy or power of the content is concentrated around one or more particular frequencies.

The value may, according to some embodiments, comprise one or more of a density value, a tonality indication, a modality indication, a peak to average ratio, and an average signal value calculated over the frequency region. The average signal value may, for example, be an average energy value or an average amplitude value. The peak to average value may, for example, be a crest factor.

The step of adjusting operation of the function for adding harmonic tones based on the spectral properties may, in some embodiments, comprise configuring the function to add at least one of the one or more harmonic tones if the spectral properties fulfil a particular criterion indicating that harmonic tones enhance the content, and configuring the function to not add any harmonic tones if the spectral properties do not fulfil the particular criterion.

The one or more spectral properties may comprise a value indicating an extent to which energy or power of the content is concentrated around one or more particular frequencies within the frequency region. In such and other embodiments, the method may further comprise comparing the value to a threshold, determining that the spectral properties fulfil the particular criterion if the value falls on a first side of the threshold, and determining that the spectral properties do not fulfil the particular criterion if the value falls on a second side of the threshold.

The step of configuring the function to add at least one of the one or more harmonic tones if the spectral properties fulfil a particular criterion may, according to some embodiments, comprise determining, based on the value, at least one of a quantity of the at least one harmonic tones, a subset of the one or more harmonic tones of the fundamental tone, wherein the at least one harmonic tones consists of the subset, and an amplitude adjustment of at least one of the at least one harmonic tones.

In some embodiments, the step of determining one or more spectral properties of the content within the frequency region may comprise determining a value comprising one or more of a density value, a tonality indication, a modality value, a peak to average ratio, and an average signal value calculated over the frequency region.

A second aspect of the invention is a computer program product comprising a computer readable medium, having thereon a computer program comprising program instructions. The computer program is loadable into a data-processing unit and adapted to cause the data-processing unit to process an audio signal with a content by execution of at least the following steps when the computer program is run by the data-processing unit: determining, based on an analysis associated with a missing fundamental phenomenon, a frequency region suitable for adding one or more harmonic tones of a fundamental tone, determining one or more spectral properties of the content within the frequency region, and adjusting operation of a function for adding harmonic tones based on the spectral properties.

According to a third aspect of the invention, an audio signal processing arrangement is provided, for processing an audio signal having a content. The arrangement comprises a missing fundamental analyzer adapted to determine a frequency region suitable for adding one or more harmonic tones of a fundamental tone, a harmonics generator adapted to generate and add harmonic tones to the audio signal, a determination unit adapted to determine one or more spectral properties of the content within the frequency region, and a control unit adapted to adjust operation of the harmonics generator based on the one or more spectral properties of the content within the frequency region.

In some embodiments, the determination unit may comprise a spectral analyzer adapted to determine a value indicating an extent to which energy or power of the content is concentrated around one or more particular frequencies within the frequency region.

In some embodiments, the determination unit may be adapted to read metadata associated with the content and comprising information relating to a value indicating an extent to which energy or power of the content is concentrated around one or more particular frequencies.

The control unit may, according to some embodiments, be adapted to configure the harmonics generator to add at least one of the one or more harmonic tones determined by the missing fundamental analyzer if the spectral properties fulfil a particular criterion indicating that harmonic tones enhance the content, and configure the harmonics generator to not add any harmonic tones if the spectral properties do not fulfil the particular criterion.

According to some embodiments, the one or more spectral properties may comprise a value indicating an extent to which energy or power of the content is concentrated around one or more particular frequencies within the frequency region. In such and other embodiments, the control unit may be further adapted to (if the spectral properties fulfil the particular criterion) determine, based on the value, at least one of a quantity of the at least one harmonic tones, a subset of the one or more harmonic tones of the fundamental tone, wherein the at least one harmonic tones consists of the subset, and an amplitude adjustment of at least one of the at least one harmonic tones. The control unit may be further adapted to configure the harmonics generator accordingly.

A fourth aspect of the invention is an electronic device comprising the arrangement according to the third aspect of the invention.

The electronic device may, according to some embodiments, be one of a mobile telephone, a music rendering device, a headset, and an earphone.

In some embodiments, the third and fourth aspects of the invention may additionally have features identical with or corresponding to any of the various features as explained above for the first aspect of the invention.

An advantage of some embodiments of the invention is that an algorithm is provided for determining whether or not missing fundamental enhancement should be used.

Another advantage of some embodiments of the invention is that content processed as suggested by embodiments of the invention is better perceived than content processed according to prior art solutions.

Another advantage of some embodiments of the invention is that simple implementations are provided for making the determination of whether or not missing fundamental enhancement should be used.

Another advantage of some embodiments of the invention is that the harmonics to be added when a missing fundamental enhancement is to be performed may be adjusted to optimize the result.

### BRIEF DESCRIPTION OF THE DRAWINGS

Further objects, features and advantages of the invention will appear from the following detailed description of embodiments of the invention, with reference being made to the accompanying drawings, in which:

FIG. 1 is a schematic drawing illustrating an example frequency spectrum and an example filter mask;

FIGS. 2A and 2B are schematic drawings illustrating example frequency spectrums;

FIG. 3 is a flowchart illustrating example method steps according to some embodiments of the invention;

FIGS. 4A and 4B are schematic drawings illustrating example missing fundamental harmonics according to some embodiments of the invention;

FIG. 5 is a schematic drawing illustrating metadata associated with audio data according to some embodiments of the invention;

FIGS. 6A and 6B are block diagrams illustrating example arrangements according to some embodiments of the invention;

FIG. 7 is a schematic drawing illustrating an example mobile terminal and an example set of headphones, each of which may comprise an arrangement according to some embodiments of the invention; and

FIG. 8 is a schematic drawing illustrating a computer program product according to some embodiments of the invention.

### DETAILED DESCRIPTION

In the following, embodiments of the invention will be described where an audio signal with a particular content undergoes an analysis associated with a missing fundamental phenomenon to determine harmonics that may be suitable to add to the signal. Such analysis is well known in the art (e.g. missing fundamental analysis) and any suitable (known or future) algorithm may be used to perform the analysis. The harmonics resulting from the analysis together define a frequency region (e.g. a frequency interval) comprising the harmonics. The frequency interval may, for example, be defined as the frequencies between and including the lowest and highest harmonic frequencies. Alternatively, the frequency interval may be defied as having a lower boundary at a particular distance below the lowest harmonic frequency and an upper boundary at a particular distance above the highest harmonic frequency. Numerous other interval definitions may also be applicable. For example, a lower boundary may be defined as above and a range span of the interval yields the upper limit. Alternatively or additionally, only harmonics that have an amplitude above an amplitude threshold may be considered when determining the interval, or a number of highest harmonics may always be excluded when determining the interval. In some examples, a frequency region may also be defined as having a lower limit defined according to any of the examples given above and having no upper limit (or defining the upper limit as infinity). In yet other examples, a frequency region may be defined as having a lower limit equal to zero (Hertz) and having either no upper limit or an upper limit defined according to any of the examples given above.

Then, embodiments of the invention may analyze the signal complexity of the content to determine whether or not (and possibly to what extent) it is suitable to add the determined harmonics to the audio content. The analysis may involve spectrum analysis. The spectrum analysis may involve any (known or future) analysis method which is suitable for determining whether or not missing fundamental enhancement should be used. Such spectrum analysis may involve, but is not limited to, determination of a value indicating an extent to which energy or power of the content is concentrated around one or more particular frequencies (thus defining a distribution measure defining e.g. how pronounced peaks of the spectrum are) within a particular frequency region, determination of a spectrum density value, determination of an amount of signal energy within a particular frequency interval (e.g. an average energy), determination of a peak to average ratio of a signal within a particular frequency interval, determination of an average amplitude of a signal within a particular frequency interval, and/or determination of a tonality and/or modality of a signal within a particular frequency region.

More generally, ne or more spectral properties of the content within the frequency region of the harmonics are determined and the spectral properties are used to adjust the audio processing. In some embodiments, the adjustment may comprise turning on or off the harmonics addition based on the result of the spectrum analysis. In some embodiments, the adjustment may comprise additional control of the harmonics addition (e.g. adjusting the amount of enhancement to be applied).

For example, a lesser number of harmonics may be added than the number determined by the missing fundamental analysis, and the number of harmonics added may be based on the spectral properties. The adjustment may also comprise selection of which harmonics to add. Such a selection may also be based on the spectral properties. As an example, a harmonic determined by the missing fundamental analysis may lie close to a peak in the spectrum of the content. In such an example, adding that harmonic may not be very beneficial and thus, that harmonic may be excluded in the selection.

Alternatively or additionally, the amplitude of one or more of the determined harmonics may be adjusted (i.e. raised or lowered). All of the harmonics that are to be added may undergo the same amount of amplitude adjustment, or the amplitude adjustment may differ between different harmonics. In some embodiments, some harmonics undergo an amplitude adjustment and some harmonics are left with unchanged amplitude.

The spectrum analysis can be performed in real time or using some sort of smoothing or averaging (e.g. filtering). In some embodiments, the spectrum analysis may be performed beforehand and information regarding the result may be associated with the content (e.g. in the form of metadata). Thus, the spectrum analysis and its result may be momentary, concerning only a particular time sample of the content, or it may concern a number of time samples of the content (such that a larger part of the content, or even an entire musical piece, is associated with a single spectrum analysis result).

The determination of the one or more spectral properties may comprise calculating, in the spectral analysis, a value which indicates to which extent the spectrum is concentrated around (or to) one or more particular frequencies within the frequency region. Thus, the value is a measure of how close to discrete or how “peaky” the spectrum is. Such a measure may also be referred to as a tonality value or a tonality indication.

If the spectral analysis is performed beforehand as explained above, the determination of the one or more spectral properties may comprise reading metadata associated with the content and extracting there from the value, which indicates to which extent the spectrum is concentrated around (or to) one or more particular frequencies.

The value may be a binary value (indicating whether or not the determined harmonics should be added), or it may have higher resolution or even be a natural number.

Some non-limiting examples of measures that may be used as the value are a density value, a tonality indication, a modality indication, a peak-to-average value (e.g. a crest factor—a peak to root mean square (rms) value) and an average value (e.g. an rms value or an amplitude mean value), both calculated over the frequency interval of the determined harmonics using momentary or time filtered samples.

Adjusting the processing based on the spectral properties may involve an investigation of whether or not the spectral properties fulfil one or more particular criteria.

For example, the value may fall above or below a comparison threshold (or may have one of two binary values) which indicates whether or not harmonics should be added. The comparison threshold may have a predetermined value or it may be adaptive (for example in relation to a filtered version of the value). Typically, if the value indicates that the spectrum is sparse harmonics should not be added (or should be added with a low power). However, embodiments of the invention may be configured differently.

The value may also be used to determine other adjustments (e.g. amount/selection of harmonics and their respective amplitudes).

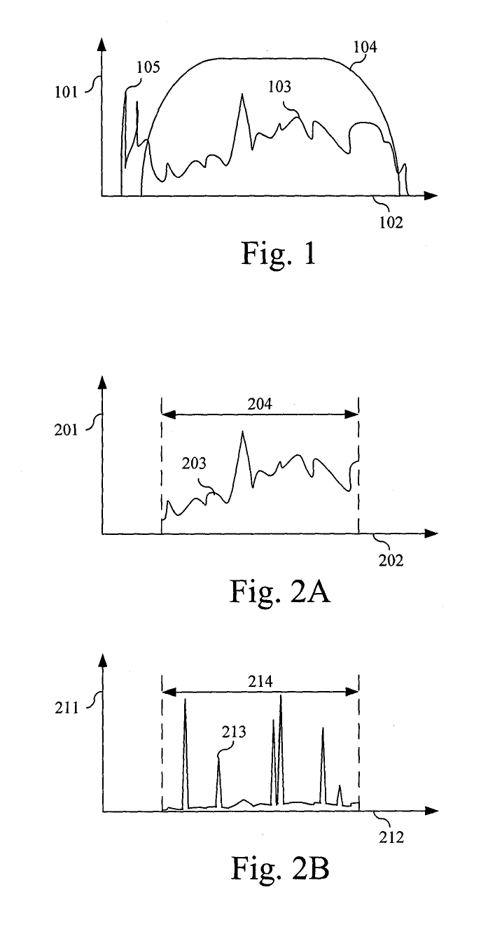

FIG. 1 is a schematic drawing illustrating an example frequency spectrum 103 and an example filter mask 104. The horizontal axis 102 schematically represents frequency, and the vertical axis 101 schematically represents a signal strength value (e.g. amplitude, power, or energy). The example frequency spectrum 103 may be a momentary spectrum of an audio signal having e.g. musical content. In this example, the audio signal is filtered with a filter having a particular frequency mask 104. Filtering of signals may be performed for various reasons, e.g. to fit a loudspeaker characteristic, to fit a transmission or storage medium characteristic, or to compress the content. When the audio signal 103 is filtered with the mask 104 it can be seen that certain frequency parts of the audio signal (e.g. the bass component 105) will be removed from the content which may negatively affect the listening experience. Thus, a missing fundamental analysis performed on the filtered signal might suggest addition of harmonics of the fundamental tone 105 to enhance the quality.

FIGS. 2A and 2B are schematic drawings illustrating example frequency spectrums 203 and 213. The horizontal axes 202, 212 schematically represent frequency, and the vertical axes 201, 211 schematically represent a signal strength value (e.g. amplitude, power, or energy). The example frequency spectrum 203 may be a momentary spectrum of an audio signal representing e.g. a pop song. The example frequency spectrum 213 may be a momentary spectrum of an audio signal representing e.g. a piano piece. The indicated frequency intervals 204, 214 may be frequency intervals of harmonics determined by a missing fundamental analysis as explained above. A content represented by a relatively high-density spectrum, such as the spectrum 203, may benefit from a missing fundamental enhancement (i.e. addition of the determined harmonics), while an addition of such harmonics to a content represented by a relatively low-density spectrum, such as the spectrum 213, may be perceived as distortion and thus worsen the listening experience.

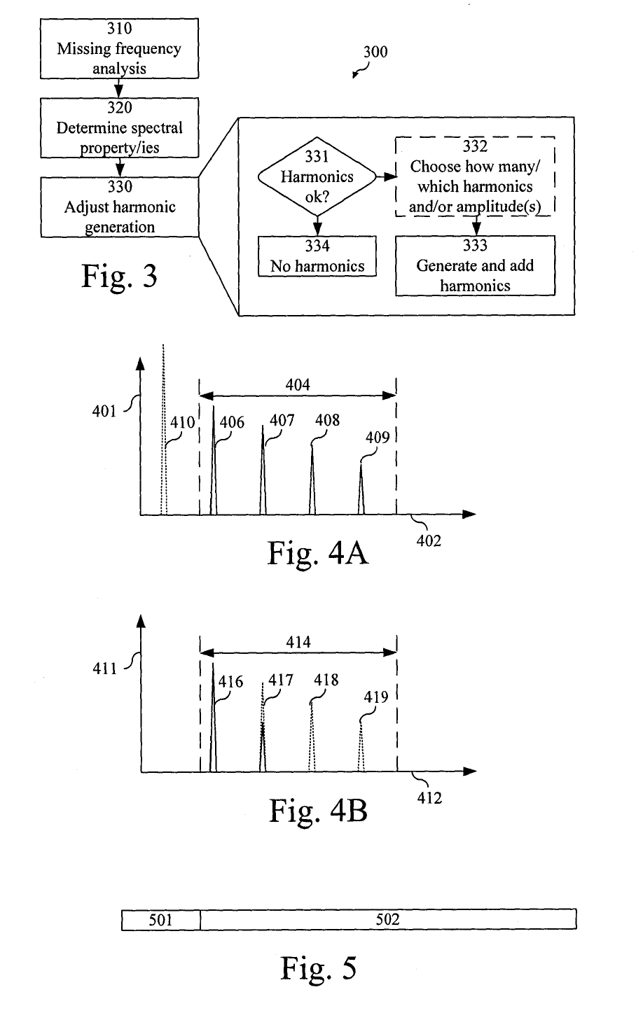

FIG. 3 illustrates an example method 300 that provides a way to differentiate between different spectrum types (such as the spectra 203, 213) and determine whether and to what extent harmonic tones of a missing fundamental analysis should be added.

The method starts in step 310, where a missing frequency analysis is performed on a signal having a content according to any suitable (known or future) algorithm. As explained above, such an analysis results in a number of determined harmonic tones and a corresponding frequency region.

In step 320, one or more spectral properties of the signal within the frequency region are determined. As explained above, the determination may involve spectral analysis and/or extraction of information from metadata associated with the content. The spectral properties may comprise a value indicating a level of peak pronunciation of the spectrum.

The determined spectral properties are used in step 330 to determine whether and to what extent the determined harmonics should be added. Step 330 may involve providing commands to a harmonics generator, wherein the commands may indicate at which frequencies harmonic tones should be generated and their respective amplitude (or power).

The adjustment of harmonics generation in step 330 may involve determining whether or not harmonics should be added at all as illustrated in sub-step 331. The determination may, for example, comprise comparison of a value indicating a level of peak pronunciation of the spectrum to a comparison threshold as explained above, or it may comprise determining which of two possible binary values the value has.

If harmonics are to be added a corresponding command may be provided and the harmonics are generated and added (sub-step 333). If, on the other hand, harmonics should not be added a corresponding command (or no command) may be provided and no harmonics are generated or added (sub-step 334).

If harmonics are to be added, the corresponding command may also include information regarding how many and/or which harmonics should be added, and/or information regarding their respective signal strength (optional sub-step 332).

FIGS. 4A and 4B illustrate an example operation of optional sub-step 332. The horizontal axes 402, 412 schematically represent frequency, and the vertical axes 401, 411 schematically represent a signal strength value (e.g. amplitude, power, or energy). Spectrum peaks 406, 407, 408, 409 represent harmonics of a fundamental tone 410 determined by a missing fundamental analysis, for example, according to the operations of step 310. The indicated frequency intervals 404, 414 represent the corresponding frequency interval as explained above. FIG. 4B illustrates the actually added harmonics after determination (for example, according to the operations of step 320) of spectral properties of the corresponding audio signal in the frequency interval 404, 414. In this example, it is determined, based on the spectral properties, to add harmonic 406 with unchanged amplitude (which is illustrated at 416), to add harmonic 407 with lowered amplitude (which is illustrated at 417), and to not add harmonics 408 and 409 (which is illustrated at 418 and 419).

FIG. 5 illustrates metadata 501 associated with audio data 502 according to some embodiments of the invention. The metadata may comprise only information regarding the one or more spectral properties or it may comprise other information as well. For example, the metadata may comprise a single value indicating a level of peak pronunciation of the spectrum relating to the entire audio data 502. Alternatively or additionally, it may comprise a plurality of values indicating a level of peak pronunciation of the spectrum each relating to a particular part of the audio data 502. The content of the audio data 502 may, for example, be an entire musical piece or parts of a musical piece (e.g. a data packet suitable for transmission over or storing on an electronic transmission or storage medium). The metadata 501 may, for example, be associated with the audio data 502 in the form of a file heading or a packet header.

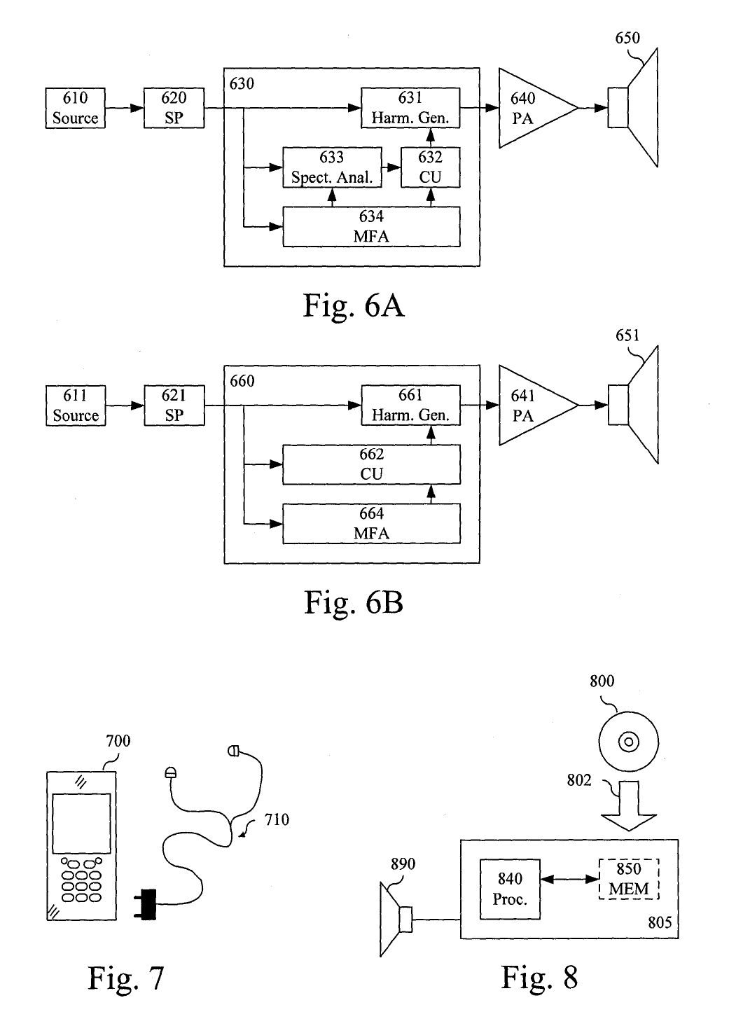

FIGS. 6A and 6B illustrate example arrangements 630 and 660 according to some embodiments of the invention. The example arrangements 630 and 660 may, for example, be adapted to carry out method steps as described in connection to FIG. 3.

In FIG. 6A, a signal source 610 generates or holds in storing an audio signal. The source may, for example, be a microphone or a buffer or other memory unit holding an audio file. The signal source 601 may also represent a receiver for receiving an audio signal.

The signal source 601 is adapted to forward the audio signal to a signal processing block (SP) 620, which is in turn adapted to process the audio signal according to any suitable (known or future) audio signal processing algorithms. The signal processing block 620 may, for example, comprise one or more filters, an equalizer and/or a compressor. The signal processing block 620 may comprise one or several signal processors, each of which may be implemented in hardware or software (e.g. using a digital signal processor—DSP) or a combination of hardware and software. In some embodiments, the signal processing block 620 is omitted.

The signal processing block 620 is adapted to forward the processed audio signal to the arrangement 630. The arrangement 630 comprises a missing fundamental analyzer (MFA) 634, a control unit (CU) 632, a spectral analyzer 633 and a harmonics generator 631.

The missing fundamental analyzer 634 is adapted to analyze the audio signal and produce one or more harmonics of a missing fundamental tone and a corresponding frequency region as explained above (compare for example with step 310 of FIG. 3).

The spectral analyzer 633 is a determination unit adapted to analyze the spectrum of the audio signal within the frequency region provided by the missing fundamental analyzer 634 as explained above (compare for example with step 320 of FIG. 3), and to output one or more corresponding spectral property indications (e.g. a value indicating a level of peak pronunciation of the spectrum).

The control unit 632 is adapted to determine whether or not the harmonics provided by the missing fundamental analyzer 634 are to be added to the audio signal based on the one or more spectral property indications provided by the spectral analyzer 633 as explained above (compare for example with step 330 and sub-step 331 of FIG. 3). In some embodiments, the control unit 632 is also adapted to determine to what extent the harmonics provided by the missing fundamental analyzer 634 are to be added to the audio signal based on the one or more spectral property indications provided by the spectral analyzer 633 as explained above (compare for example with sub-step 332 of FIG. 3).

The control unit 632 is adapted to provide commands to the harmonics generator 631 in accordance with its determinations. The commands may indicate at which frequencies harmonics should be added and their respective amplitude or power. The harmonics generator 631 is adapted to generate harmonic tones as indicated by the commands from the control unit 632 and to add the harmonic tones to the audio signal as explained above (compare for example with sub-step 333 of FIG. 3). The audio signal is thereafter output from the arrangement 630.

The arrangement 630 may be implemented in hardware or software or a combination of hardware and software. In some embodiments, the arrangement 630 and at least part of the signal processing block 620 is implemented as a single unit (e.g. using a DSP).

After having processed the audio signal, the arrangement 630 is adapted to forward the processed audio signal, which now may or may not comprise added harmonics, to a power amplifier (PA) 640, which is adapted to amplify the audio signal according to any suitable amplification method and forward it to an audio rendering unit (e.g. a loudspeaker 650).

Turning to FIG. 4B, the signal source 611, the signal processing block 621, the power amplifier 641 and the loudspeaker 651 are identical or similar to the corresponding items 610, 620, 640, 650 of FIG. 6A, and are therefore not described in detail.

The signal processing block 621 is adapted to forward the processed audio signal to the arrangement 660. The arrangement 660 comprises a missing fundamental analyzer (MFA) 664, a control unit (CU) 662 and a harmonics generator 661.

The missing fundamental analyzer 664 and the harmonics generator are identical or similar to the corresponding items 634 and 631 of FIG. 6A, and are therefore not described in detail either.

The control unit 662 comprises a determination unit adapted to read metadata associated with the audio signal to extract information regarding one or more corresponding spectral property indications (e.g. a value indicating a level of peak pronunciation of the spectrum) as explained above (compare for example with step 320 of FIG. 3).

The control unit 662 is also adapted to determine whether or not the harmonics provided by the missing fundamental analyzer 664 are to be added to the audio signal based on the one or more spectral property indications provided by the metadata as explained above (compare for example with step 330 and sub-step 331 of FIG. 3). In some embodiments the control unit 662 is also adapted to determine to what extent the harmonics provided by the missing fundamental analyzer 664 are to be added to the audio signal based on the one or more spectral property indications as explained above (compare for example with sub-step 332 of FIG. 3).

The control unit 662 is adapted to provide commands to the harmonics generator 661 in accordance with its determinations. As above, the commands may indicate at which frequencies harmonics should be added and their respective amplitude or power.

The arrangement 660 may be implemented in hardware or software or a combination of hardware and software. In some embodiments, the arrangement 660 and at least part of the signal processing block 621 is implemented as a single unit (e.g. using a DSP).

FIG. 7 illustrates an example mobile terminal 700 and an example set of headphones 710, each of which may comprise an arrangement and/or perform a method according to some embodiments of the invention. The mobile terminal 700 and/or the headphones 710 may, for example, comprise an arrangement as described in connection to any of the FIGS. 6A-B. Alternatively or additionally, the mobile terminal 700 and/or the headphones 710 may, for example, perform method steps as described in connection to FIG. 3.

As indicated by the examples provided in FIG. 7, embodiments of the invention may be particularly useful when the audio content is to be reproduced by small loudspeakers. However, application of embodiments of the invention is not limited to such cases. Contrarily, embodiments of the invention are equally applicable to any audio processing applications.

Furthermore, embodiments of the invention are equally applicable to any audio content (e.g. speech) although many of the examples have been provided in relation to musical content.

The described embodiments of the invention and their equivalents may be realised in software or hardware or a combination thereof. They may be performed by general-purpose circuits associated with or integral to an audio rendering device, such as digital signal processors (DSP), central processing units (CPU), co-processor units, field-programmable gate arrays (FPGA) or other programmable hardware, or by specialized circuits such as for example application-specific integrated circuits (ASIC). All such forms are contemplated to be within the scope of the invention.

The invention may be embodied within an electronic apparatus comprising circuitry/logic or performing methods according to any of the embodiments of the invention. The electronic apparatus may, for example, be a portable or handheld mobile radio communication equipment, a mobile radio terminal, a mobile telephone, a communicator, an electronic organizer, a smartphone, a headset, an earphone or a pair of earphones, a headphone or a pair of headphones, a computer, a notebook, a mobile gaming device, or a (wrist) watch.

According to some embodiments of the invention, a computer program product comprises a computer readable medium such as, for example, a diskette or a CD-ROM. The computer readable medium may have stored thereon a computer program comprising program instructions. The computer program may be loadable into a data-processing unit, which may, for example, be comprised in an audio rendering device. When loaded into the data-processing unit, the computer program may be stored in a memory associated with or integral to the data-processing unit. According to some embodiments, the computer program may, when loaded into and run by the data-processing unit, cause the data-processing unit to execute method steps according to, for example, the method shown in FIG. 3.

FIG. 8 is a schematic drawing illustrating a computer readable medium in the form of a CD-ROM 800 according to some embodiments of the invention. The CD-ROM 800 may have stored thereon a computer program comprising program instructions. The computer program may be loadable (as shown by arrow 802) into an electronic device 805 comprising a processing unit 840 and possibly a separate memory unit 850, and being connectable to an audio rendering unit 890. When loaded into the electronic device 805, the computer program may be stored in the memory unit 850. According to some embodiments, the computer program may, when loaded into the electronic device 805 and run by the processing unit 840, cause the electronic device 805 to execute method steps according to, for example, the method shown in FIG. 3.

The invention has been described herein with reference to various embodiments. However, a person skilled in the art would recognize numerous variations to the described embodiments that would still fall within the scope of the invention. For example, the method embodiments described herein describes example methods through method steps being performed in a certain order. However, it is recognized that these sequences of events may take place in another order without departing from the scope of the invention. Furthermore, some method steps may be performed in parallel even though they have been described as being performed in sequence.

In the same manner, it should be noted that in the description of embodiments of the invention, the partition of functional blocks into particular units is by no means limiting to the invention. Contrarily, these partitions are merely examples. Functional blocks described herein as one unit may be split into two or more units. In the same manner, functional blocks that are described herein as being implemented as two or more units may be implemented as a single unit without departing from the scope of the invention.

Hence, it should be understood that the limitations of the described embodiments are merely for illustrative purpose and by no means limiting. Instead, the scope of the invention is defined by the appended claims rather than by the description, and all variations that fall within the range of the claims are intended to be embraced therein.

1. A method of processing an audio signal with a content comprising:
determining, based on an analysis associated with a missing fundamental phenomenon, a frequency region suitable for adding one or more harmonic tones of a fundamental tone;
determining one or more spectral properties of the content within the frequency region; and
adjusting operation of a function for adding harmonic tones based on the spectral properties.

2. The method of claim 1, wherein the step of determining one or more spectral properties of the content within the frequency region comprises:
determining, via spectrum analysis, a value indicating an extent to which energy or power of the content is concentrated around one or more particular frequencies within the frequency region.

3. The method of claim 1, wherein the step of determining one or more spectral properties of the content within the frequency region comprises:
reading metadata associated with the content and comprising information relating to a value indicating an extent to which energy or power of the content is concentrated around one or more particular frequencies.

4. The method of claim 2, wherein the value comprises one or more of:
a density value;
a tonality indication;
a modality indication;
a peak to average ratio; and
an average signal value calculated over the frequency region.

5. The method of claim 1, wherein the step of adjusting operation of the function for adding harmonic tones based on the spectral properties comprises:
configuring the function to add at least one of the one or more harmonic tones if the spectral properties fulfil a particular criterion indicating that harmonic tones enhance the content; and
configuring the function to not add any harmonic tones if the spectral properties do not fulfil the particular criterion.

6. The method of claim 5, wherein the one or more spectral properties comprises a value indicating an extent to which energy or power of the content is concentrated around one or more particular frequencies within the frequency region, and further comprising:
comparing the value to a threshold;
determining that the spectral properties fulfil the particular criterion if the value falls on a first side of the threshold; and
determining that the spectral properties do not fulfil the particular criterion if the value falls on a second side of the threshold.

7. The method of claim 6, wherein the step of configuring the function to add at least one of the one or more harmonic tones if the spectral properties fulfil a particular criterion comprises determining, based on the value, at least one of:
a quantity of the at least one harmonic tones;
a subset of the one or more harmonic tones of the fundamental tone, wherein the at least one harmonic tones consists of the subset; and
an amplitude adjustment of at least one of the at least one harmonic tones.

8. The method of claim 1, wherein the step of determining one or more spectral properties of the content within the frequency region comprises determining a value comprising one or more of:
a density value;
a tonality indication;
a modality indication;
a peak to average ratio; and
an average signal value calculated over the frequency region.

9. A computer program product comprising a computer readable medium, having thereon a computer program comprising program instructions, the computer program being loadable into a data-processing unit and adapted to cause the data-processing unit to process an audio signal with a content by execution of at least the following steps when the computer program is run by the data-processing unit:
determining, based on an analysis associated with a missing fundamental phenomenon, a frequency region suitable for adding one or more harmonic tones of a fundamental tone;
determining one or more spectral properties of the content within the frequency region; and
adjusting operation of a function for adding harmonic tones based on the spectral properties.

10. An audio signal processing arrangement for processing an audio signal having a content, the arrangement comprising:
a missing fundamental analyzer adapted to determine a frequency region suitable for adding one or more harmonic tones of a fundamental tone;
a harmonics generator adapted to generate and add harmonic tones to the audio signal;
a determination unit adapted to determine one or more spectral properties of the content within the frequency region; and
a control unit adapted to adjust operation of the harmonics generator based on the one or more spectral properties of the content within the frequency region.

11. The arrangement of claim 10, wherein the determination unit comprises a spectral analyzer adapted to:
determine a value indicating an extent to which energy or power of the content is concentrated around one or more particular frequencies within the frequency region.

12. The arrangement of claim 10, wherein the determination unit is adapted to:
read metadata associated with the content and comprising information relating to a value indicating an extent to which energy or power of the content is concentrated around one or more particular frequencies.

13. The arrangement of claim 10, wherein the control unit is adapted to:
configure the harmonics generator to add at least one of the one or more harmonic tones determined by the missing fundamental analyzer if the spectral properties fulfil a particular criterion indicating that harmonic tones enhance the content; and
configure the harmonics generator to not add any harmonic tones if the spectral properties do not fulfil the particular criterion.

14. The arrangement of claim 13, wherein the one or more spectral properties comprises a value indicating an extent to which energy or power of the content is concentrated around one or more particular frequencies within the frequency region, and wherein the control unit is further adapted to—if the spectral properties fulfil the particular criterion—determine, based on the value, at least one of:
a quantity of the at least one harmonic tones;
a subset of the one or more harmonic tones of the fundamental tone, wherein the at least one harmonic tones consists of the subset; and
an amplitude adjustment of at least one of the at least one harmonic tones;
and to configure the harmonics generator accordingly.

15. An electronic device comprising the arrangement of claim 10.

16. The electronic device of claim 15, wherein the electronic device is one of a mobile telephone, a music rendering device, a headset, and an earphone.
